(19) United States
(12) Patent Application Publication
(10) Pub. No.: US 2015/0219709 A1
(43) Pub. Date: Aug. 6, 2015

(54) REMOTELY ALIGNED WAFER PROBE STATION FOR SEMICONDUCTOR OPTICAL ANALYSIS SYSTEMS

(71) Applicant: Checkpoint Technologies LLC, San Jose, CA (US)

(72) Inventors: Joshua Munoz, San Jose, CA (US); Thomas Clawges, Pleasanton, CA (US)

(73) Assignee: Checkpoint Technologies LLC, San Jose, CA (US)

(21) Appl. No.: 14/173,722

(22) Filed: Feb. 5, 2014

(51) Int. Cl. G01R 31/26; G01R 1/04; G01N 21/01; G01R 31/28; G01N 21/84

(52) U.S. Cl. CPC G01R 31/2601; G01R 31/2893; G01N 21/84; G01N 21/01; G01R 1/04; G01N 2021/0106

(57) ABSTRACT

A test station holds a semiconductor wafer during electrical testing with an electrical test apparatus and optical inspection with an optical system. The test station allows wafer probing to be aligned external to the optical system. After the wafer is in alignment, the test station may be transported to the optical system for inspection from a back side of the wafer while having electrical testing by the electrical test apparatus from the front side. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### FIELD OF THE DISCLOSURE

Embodiments of the present disclosure relate to semiconductor test equipment, and more particularly to methods and equipment for wafer level integrated circuit (IC) testing.

### BACKGROUND

Generally, integrated circuits (IC) are fabricated by forming a number of identical IC devices (i.e., dies) on a wafer through fabrication process involving techniques such as photolithography and deposition, followed by separating each die from the wafer for packaging. Physical defects in the wafer and defects in the manufacturing processing may result in defective dies on the wafer. Thus, it is desirable for semiconductor fabricators to perform wafer level IC testing before a wafer is diced and mounted in packages, modules or on a printed circuit board. Wafer level IC testing becomes critical to the semiconductor manufacturing process because it identifies ICs that do not function properly, thus eliminating faulty die prior to the costly packaging step and providing feedback for improving product design.

Conventional wafer level IC testing usually evaluates performance characteristics of dies in a test station by establishing electrical connectivity between the contact location (e.g., input/output contact pads, bond pads, fuse pads, test pads) on each individual die and external test equipment. Conventional test equipment is a wafer tester to make pressure connections to contact pads on the die for defects. The wafer tester usually has a probe card with electrical contact points (i.e., probe pins) that match the size and density of the contact pads on the die to be tested. The probe card provides an electrical path between the tester and the contact pads through the probe pins. In addition, the wafer tester includes certain circuitry that is electrically coupled to the probe pins and able to generate, detect and measure electrical signals in a manner suitable to determine the performance of the individual die on the wafer or device under test.

Optical systems, such as infrared microscopes, have been used to inspect semiconductor devices after dicing. It is desirable to have optical/image inspection on dies prior to dicing in addition to electrical testing and thus two separate test tools are required. Such configuration requires additional time to set up and align the wafer to the electrical probes of the electrical test apparatus and lens tip of the optical system. As such, it increases the cost for wafer level IC testing.

It is within this context that embodiments of the present invention arise.

### SUMMARY OF THE INVENTION

According to aspects of the present disclosure, a test station for holding a semiconductor wafer for testing semiconductor dies on the wafer comprises a bottom section configured to interface with a first test tool provided underneath the test station, a top section configured to interface with a second test tool provided above the test station and a chuck section provided between the bottom section and the top section, configured to hold and secure the wafer. The bottom section includes a first plate with a first opening to accommodate a top portion of the first testing tool. The top section includes a second plate with a second opening for the second test tool to access the wafer. The chuck section is configured to move the wafer relatively with respect to the bottom section and the top section for wafer alignment to align points of interest on the wafer with the first and second openings for the first and second test tools to access for testing/inspection.

In some implementations, the wafer alignment is performed remotely from the first test tool.

In some implementations, the test station further comprises a wheel cart to carry and transport the test station.

In some implementations, the first test tool is an optical system, such as an inverted upward looking silicon immersion lens (SIL) microscope, electron/ion beam systems, or other conventional optical systems.

In some implementations, the second test tool is an electrical test apparatus including a probe card and a plurality of probe pins.

According to an aspect of the present disclosure, a system comprises at least two test stations according to the embodiments of the present disclosure, a first test tool provided underneath the first test station, a second test tool provided above the first station. A first test station holds a first semiconductor wafer and a second test station holds a second semiconductor wafer. The first test station is configured to be removed from the first or second test tools and replaced by the second test station.

### BRIEF DESCRIPTION OF THE DRAWINGS

Objects and advantages of the invention will become apparent upon reading the following detailed description and upon reference to the accompanying drawings in which:

FIG. 1 is an overview diagram of a probe station provided between an electrical test apparatus and an optical system according to an aspect of the present disclosure.

FIG. 2 is a schematic diagram of a probe station according to an aspect of the present disclosure.

FIG. 3 is a top view of a chuck section in a probe station according to an aspect of the present disclosure.

FIG. 4 is a cross-sectional view of portions of a probe station according to an aspect of the present disclosure.

FIG. 5 is a top view of a cart transporting a probe station according to an aspect of the present disclosure

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the exemplary embodiments of the invention described below are set forth without any loss of generality to, and without imposing limitations upon, the claimed invention. The drawings showing illustrations in accordance with examples of embodiments are described in enough detail to enable those skilled in the art to practice the present subject matter. The embodiments can be combined, other embodiments can be utilized, or structural, logical, and electrical change can be made without departing from the scope of what is claimed. In this regard, directional terminology, such as “top”, or “bottom” etc. is used with reference to the orientation of the figure(s) being described. Additionally, because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. In this document, the terms, “optional” or “optionally” means that the subsequently described circumstance may or may not occur, so that the description includes instances where the circumstance occurs and instances where it does not. In this document, the terms “a” and “an” are used, as is common in patent documents, to include one or more than one. In this document, the term “or” is used to refer to a nonexclusive “or,” such that “A or B” includes “A but not B,” “B but not A,” and “A and B,” unless otherwise indicated. The following detailed description, therefore, is not to be taken in a limiting sense, and the scope of the present invention is defined by the appended claims.

In order to provide electrical testing and optical inspection on dies prior to dicing, it is preferable to have the optical system configured to optically probe the chip from the back side of the wafer while the device is powered up from the front side for electrical probing. Embodiments according to the present disclosure are a probe station holding a workpiece for electrical testing with an electrical test apparatus and optical inspection with an optical system. A probe station according to the embodiments of the present disclosure allows wafer probing to be aligned external to the optical system. That is, with two or more probe stations according to the embodiments of the present disclosure, a first wafer on a first probe station may be aligned for probing off the optical system and a second wafer on a second probe station that has been aligned can be put on the optical system for optical inspection from the back side of the wafer while having electrical testing from the front side. Accordingly, the optical system may retain its full tester docking functionality. Optionally, electrical tests may be performed remotely before transferring the probe station to the optical system. No change or alternation to the electrical test apparatus or optical system is required with a probe station according to the embodiments of the present disclosure.

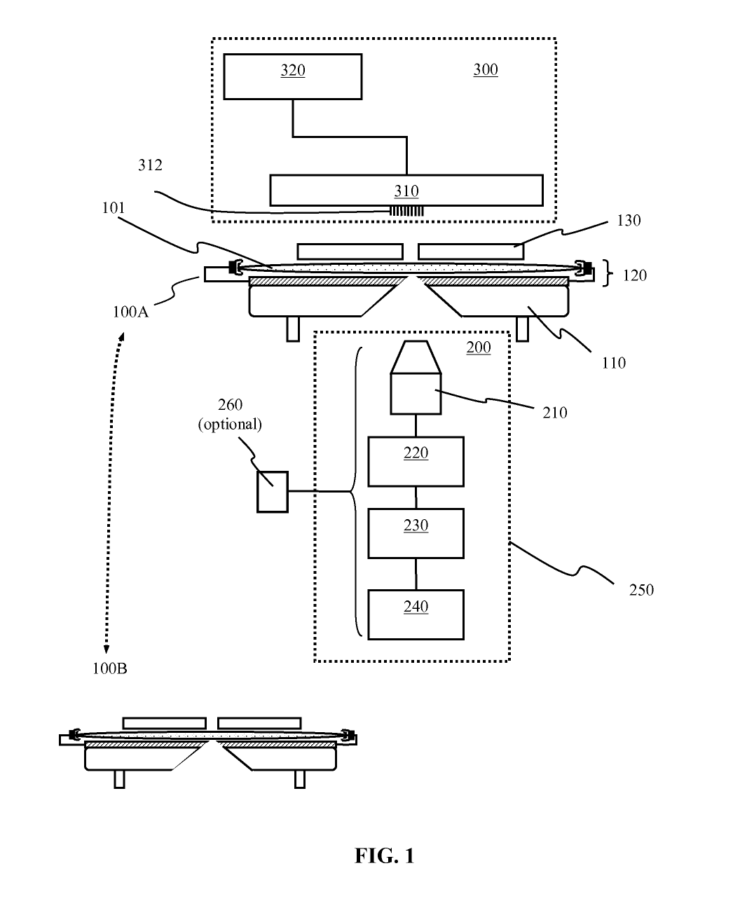

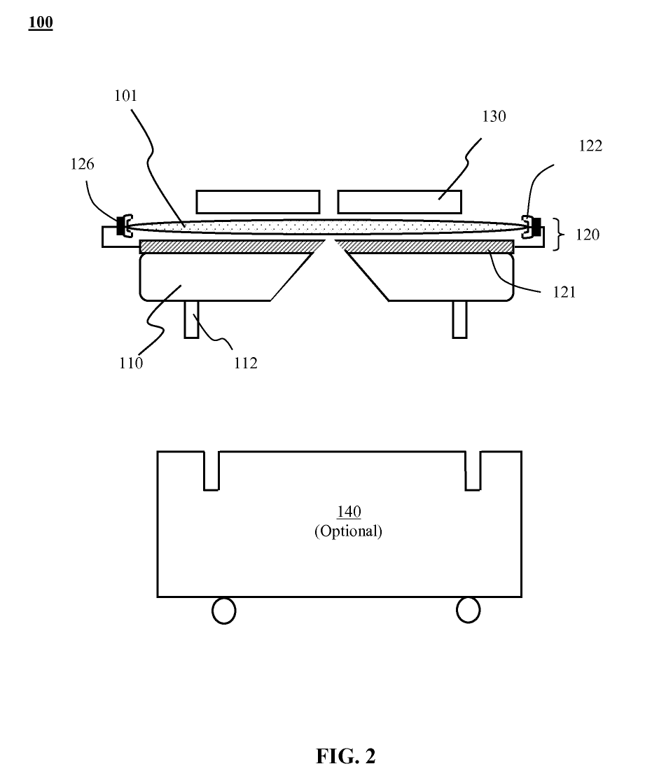

FIG. 1 is an overview diagram showing a probe station provided between an electrical test apparatus and an optical system according to embodiments of the present disclosure. The probe station 100A includes a bottom section 110 for interface with an optical system 200, a top section 130 for interface with an electrical test apparatus 300 and a chuck section 120 between the bottom section 110 and the top section 130 for holding a workpiece/wafer 101 for alignment, testing and inspection. The details of the probe station 100A will be described later in connection with FIGS. 2-5.

With reference to FIG. 1, the probe station 100A is provided between the optical system 200 and the electrical test apparatus 300. The optical system 200 is provided or mounted underneath the probe station 100A. The probe station 100A is designed to be readily placed in position proximate the optical system and readily removed. In one example, the probe station 100A may be placed on a test table 250 where the optical system 200 is provided below. In one embodiment, the optical system 200 may be any inverted conventional optical system or electron/ion beam system. By way of example but no by way of limitation, the optical system 200 is an inverted upward looking silicon immersion lens (SIL) microscope, such as an InfraScan inverted system from Checkpoint Technologies of San Jose, Calif. Generally, the optical system 200 includes an objective 210, optics 220, a detection device 230 and a controller 240. The objective 210 has one or more objective optical elements (e.g., SIL or other lenses) configured to transmit light rays received from the workpiece/wafer to optics 220. The optics 220 is configured to focus the light rays onto the detection device 230 (e.g., an image detector array, an image capture device) for image capture. The captured image is then inspected and analyzed by the controller 240. Optionally, the optical inspection system 200 may include a display for image display and a user interface device (e.g., keyboard or mouse). Optionally, the optical system 200 may connect to a positioning component such as an actuator 260 or similar device which causes the objective optical elements to move/slide relatively to the probe station 100A and align with the opening on the bottom section 110 of the probe station 100.

The electrical test apparatus 300 may be mounted over the probe station 100A. In one embodiment, the electrical test apparatus is a wafer tester including a probe card 310 and tester electronics 320. The probe card 310 includes a printed circuit board connected to a plurality of probe pins 312 configured to making electrical connection between contact pads on a specific die and external tester electronics 320. The probe pins 312 may be an array of fine wires, formed springs or similar conductive elements. The tester electronics 320 are circuitry electrically coupled to the probe card 310 and are configured to manage the signals that are used for performing the test. Specifically, the tester electronics 320 generate test signals (i.e., test stimulus, such as commands, memory location addresses) and send to each die to be tested through the probe card 310. The tester electronics 320 then receive response signals generated by the ICs integrated in each die in response to the test stimulus through the probe card 310. The response signals are processed by the tester electronics 320 to identify malfunctioning dies. In order to exchange the test and response signals between the tester electronics 320 and the dies to be tested, the contact pads on the dies and the probe pins 312 are in physical contact. In one example, the wafer is raised high enough or the probe pins (e.g., individual springs) are moved downward to create sufficient force to break through any oxides on the contact pads and make a reliable contact.

In addition, the probe pins 312 may have different arrangements to correspond to different arrangements of contact pads in dies to be tested. In one example, the probe pins may be detachable and may be replaced or adjusted in order to correspond to different arrangement structure of contact pads of the dies to be tested. Moreover, the electrical test apparatus 300 may include a positioning component (e.g., an actuator) to cause the probe card 310 to move/slide relatively to the probe station 100A.

As shown in FIG. 1, the probe station 100A may be dismounted, removed, released or detached from the optical system 200 and the electrical test apparatus 300. In other words, the probe station 100A may be taken off from the optical system 200 and test apparatus 300, and put it back without damaging it. In one embodiment, the probe station 100A may be removed and replaced by another probe station 100B. In one embodiment, the wafer on the probe station 100B can be aligned remotely from the optical system 200 for electrical probing of a single die using fiducial alignment marks of the wafer. In one embodiment, after the wafer is in alignment, the electrical probe pins will be moved into contact with the wafer, at which time electrical operation can be verified as necessary. In another embodiment, after wafer alignment, the entire probe station 100B is locked in place and transported to the optical analysis system 200 for optical inspection from the back side of the wafer while having electrical testing from the front side.

FIG. 2 shows a probe station according to an aspect of the present disclosure. The probe station 100 includes a bottom section 110, a top section 130 and a chuck section 120 between the bottom section 110 and the top section 130.

The bottom section 110 is configured to adequately center and secure the probe station 100 to the optical inspection system 200 of FIG. 1. Specifically, the bottom section 110 allows the probe station 100 to interface with the optical analysis system 200 for optical imaging and laser probing utilizing standard post-style docking interface pins. In one example, the bottom section 110 may include a plurality of stands 112 for mounting on the optical system 200. The bottom section 110 may include a bottom plate that has an opening to accommodate the top portion of an optical system (e.g., objective optical elements). In one embodiment, the bottom section 110 has a beveled opening tailored to fit the SIL profile for maximum support and accessibility of each particular SIL and to accommodate different sized dies. For example, a device or mechanism, such as an actuator, may be electrically connected to the bottom section 110 to move at least one portion of the bottom plate away from or close to the other portions of the bottom plate so as to adjust the size of the opening on the bottom section 110. In another example, the bottom section 110 may be replaced entirely by another bottom section with different opening sizes. Moreover, the bottom section 110 also provides necessary support beneath a workpiece when electrical probe pins are applied to the front side of the wafer for electrical testing.

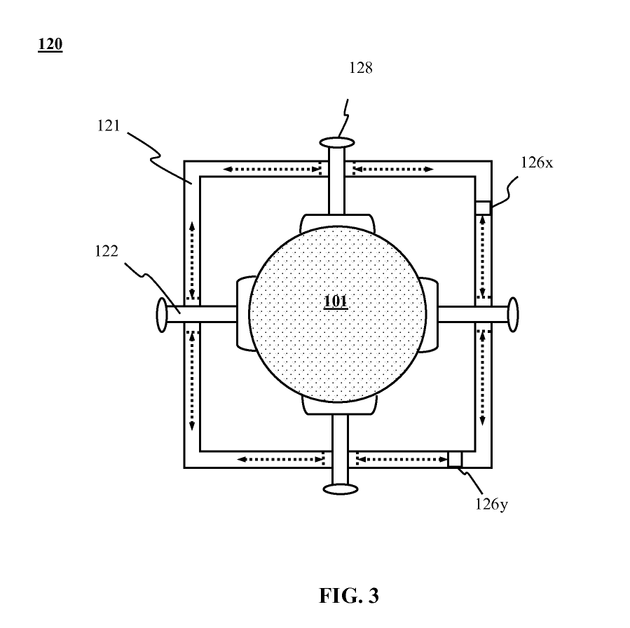

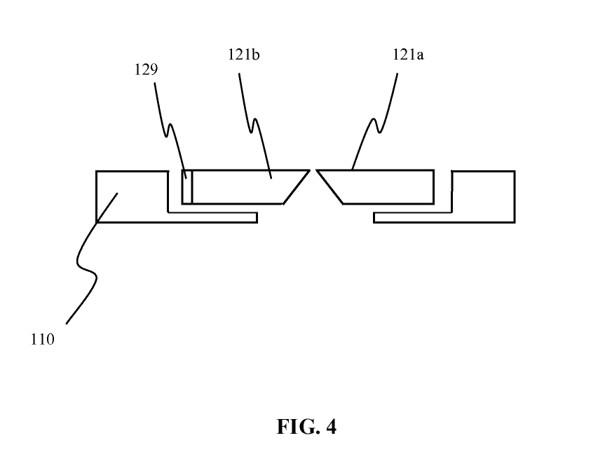

With reference to FIGS. 2 and 3, the chuck section 120 is provided above the bottom section 110 for holding a workpiece/wafer 101 for alignment, electrical testing and optical inspection. The chuck section 120 supports the workpiece 101 when probe pins are applied on the wafer for electrical testing and it also retains access to the back side of the wafer for optical inspection. The chuck section 120 may include a support plate or frame 121 and a device/mechanism connected to the support plate 121 for holding and securing the wafer by magnetic clips, mechanical or vacuum means, such as mag arm members 122. The opening on the support plate 121 can have a variable size to accommodate different sized die. In one example, the support plate 121 may have a device 129 (e.g., an actuator) as shown in FIG. 4 to control the opening size by moving at least one portion of the support plate 121a away from or close to other portions of the support plate 121b.

The chuck section 120 is configured to move the workpiece/wafer 101 relatively with respect to the bottom section 110 and the top section 130. By way of example, the chuck section may include suitably configured bearing 128 (e.g., air bearings, slide bearings) provided between the end of the arm members 122 and the support plate 121 to allow the workpiece to move along a horizontal direction (i.e., a direction in a plane where the dies are arranged), and corresponding positioning components 126x and 126y (e.g., translational step motors or actuators) positioned approximately perpendicular to each other in the horizontal plane. The positioning components 126x and 126y cause the workpiece to move/slide (i.e., linearly transfer) horizontally to align the points of interest on the workpiece with the openings in the bottom section 110 and top section 130 for objective optical elements of the optical system and corresponding probe pins to access. Optionally, another positioning component (not shown) may cause the wafer to move in a vertical direction (i.e., a direction perpendicular to the plane of the wafer) so the contact pads of the die to be tested may physically contact he probe pins by moving the wafer vertically.

Referring back to FIGS. 1 and 2, the top section 130 provides interface and support to the probe card 310 of the electrical test apparatus 300 provided above the probe station 100. In one embodiment, the top section 130 includes a top plate with an opening. In addition, the top section 130 may optionally include the imaging optics required to align the opening to probe card for its probe pins to make accurate contact with the contact pads on the die to be tested under the opening. These imaging optics for wafer alignment are not required to have high resolution or magnification. By way of example, the imaging optics may be automatic pattern recognition optics. In another example, the imaging optics may be two image capturing devices (e.g., cameras), one operable to image the probe card and one operable to image the contact pads of the die. Based on the image data collected, the top section 130 may be configured to move/slide the top plate (e.g., with a motor) and align the probe card to the corresponding contact pads through the opening on the top plate. After the wafer is in alignment, the probe pins and the corresponding contact pads make physical contact for testing by either raising the probe station 100 or moving the probe card downward. After the test, the motor in the top section 130 may step/slide the top plate so that its opening is aligned to the next die to be tested. In one embodiment, the wafer probing alignment and the electrical testing are performed off the optical system 200. In another embodiment, after the wafer is in alignment for testing, the probe station 100 may be moved to place above the optical system. With such arrangement, the electrical testing may be performed from the front side of the wafer while the optical inspection may be conducted by the optical system from the back side.

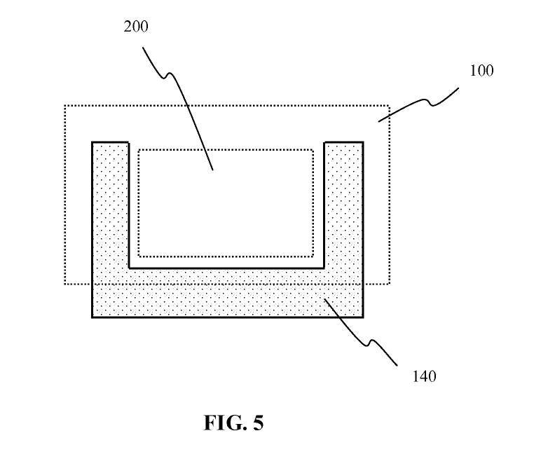

In one embodiment, the probe station 100 may be placed on a wheeled cart 140 so that the probe station can be moved around and placed over an optical system for optical inspection. The cart 140 may incorporate certain circuitry to perform electrical testing when the probe station 100 is on the cart. In addition, the cart 140 may include a mechanism to raise the mounted probe station, such as a hydraulic system. Additionally, as shown in FIG. 2, the wheel cart 140 may have a solid body with a number of holes to accommodate the stands 112 of the probe station 100. In another example as shown in FIG. 5, the cart 140 has a U shaped body for carrying the probe station. With such configuration, the U-shaped cart 140 may transport the probe station over an optical system for performing inspection directly under the cart. In addition, the U-shaped cart 140 may transport the probe station and place it to a test table with an optical system provided underneath.

The appended claims are not to be interpreted as including means-plus-function limitations, unless such a limitation is explicitly recited in a given claim using the phrase “means for.” Any element in a claim that does not explicitly state “means for” performing a specified function, is not to be interpreted as a “means” or “step” clause as specified in 35 USC §112, ¶6. In particular, the use of “step of” in the claims herein is not intended to invoke the provisions of 35 USC §112, ¶6.

What is claimed is:

1. A test station for holding a semiconductor wafer for testing semiconductor dies on the wafer, comprising:
a bottom section configured to interface with a first test tool provided underneath the test station, wherein the bottom section includes a first plate with a first opening to accommodate a top portion of the first testing tool;
a top section configured to interface with a second test tool provided above the test station, wherein the top section includes a second plate with a second opening for the second test tool to access the wafer; and
a chuck section provided between the bottom section and the top section, configured to hold and secure the wafer, wherein the chuck section is configured to move the wafer relatively with respect to the bottom section and the top section for wafer alignment to align points of interest on the wafer with the first and second openings for the first and second test tools to access for testing.

2. The test station of claim 1, wherein the test station is dismountable, removable, releasable or detachable from the first or second test tools.

3. The test station of claim 1, wherein the wafer alignment is performed remotely from the first test tool.

4. The test station of claim 1, further comprising a wheel cart configured to carry and transport the test station.

5. The test station of claim 1, wherein the bottom section is configured to adjust a size of the first opening on the bottom section.

6. The test station of claim 1, wherein the bottom section is configured to be removed and replaced by another bottom section with a difference opening size.

7. The test station of claim 1, wherein the bottom section is configured for relative movement with respect to the first test tool.

8. The test station of claim 1, wherein the first test tool is an optical system, such as an inverted upward looking SIL microscope, electron/ion beam systems, or other conventional optical systems.

9. The test station of claim 1, wherein the top section is configured for relative movement with respect to the second test tool.

10. The test station of claim 1, wherein the top section further includes imaging optics for alignment of the second opening to the test probes of the second test tool.

11. The test station of claim 1, wherein the second test tool is an electrical test apparatus including a probe card and a plurality of probe pins.

12. The test station of claim 1, wherein the chuck section further includes bearings and corresponding positioning components to cause the wafer to move along a direction in a plane where the dies are arranged.

13. The test station of claim 1, wherein the electrical test apparatus includes tester electronics and a probe card with a plurality of probe pins, wherein the probe card is configured to transmit electrical test signals between the tester electronics and a die to be tested through the probe pins and the tester electronics are configured to generate, detect and measure test and response signals to determine performance of the die to be tested.

14. A system, comprising:
at least two test stations of claim 1, a first test station holding a first semiconductor wafer and a second test station holding a second semiconductor wafer;
a first test tool provided underneath the first test station; and
a second test tool provided above the first station;
wherein the first test station is configured to be removed from the first or second test tools and replaced by the second test station.

15. The system of claim 14, wherein the first test tool is an optical system.

16. The system of claim 14, wherein the second test tool is an electrical test apparatus including a probe card with a plurality of probe pins.

17. The system of claim 14, further comprising one or more wheel cart to carry and transport the first or second test station.
